(19) United States
(12) Patent Application Publication
(10) Pub. No.: US 2025/0362331 A1
(43) Pub. Date: Nov. 27, 2025

(54) METHOD AND DEVICE FOR DETERMINING A GROUNDING IMPEDANCE

(71) Applicant: OMICRON electronics GmbH, Klaus (AT)

(72) Inventor: Josef Schmidbauer, Salzburg (AT)

(21) Appl. No.: 18/832,296

(22) PCT Filed: Jan. 25, 2023
(86) PCT No.: PCT/EP2023/051752

§ 371 Date: Jul. 23, 2024

(30) Foreign Application Priority Data
Jan. 28, 2022 (AT) A 50040/2022

(51) Int. Cl. G01R 27/20; G01R 27/18

(52) U.S. Cl. CPC G01R 27/20; G01R 27/18

(57) ABSTRACT

The present invention relates to a method (400) for determining a grounding impedance (210) of a grounding device (120) of a power engineering installation (110). The method comprises determining (406, 412) at least two impedance values on the grounding device (120), while the grounding device (120) is electrically connected to at least one further grounding device of at least one further power engineering installation (170, 180). Each of the at least two impedance values is determined with a respective test current at a specified frequency. The frequencies of the respective test currents are different. The method further comprises determining (414) at least one parameter of a model (500), which represents the grounding device (120) and the at least one further grounding device, as a function of the at least two impedance values. The at least one parameter comprises an approximate value for the grounding impedance (210) of the grounding device (120).

The present application is a U.S. National Stage of PCT International Patent Application No. PCT/EP2023/051752, filed Jan. 25, 2023, which claims priority to Austrian Application No. A 50040/2022, filed Jan. 28, 2022, both of which are hereby incorporated herein by reference.

### FIELD OF THE INVENTION

The present invention relates to a method for determining a grounding impedance of a grounding device of a power engineering installation or electrical installation, for example an overhead line pylon, and a corresponding device for determining a grounding impedance of a grounding device of a power engineering installation or electrical installation.

### BACKGROUND

In addition to the grounding resistance of the local grounding system, other components with a grounding effect, such as ground wires connected to overhead lines and additional grounding system connected to it, flow into the ground resistance, as defined for example in EN 50522. A grounding impedance, which represents the alternating current resistance between the grounding electrode and the reference ground, is considered in particular for AC systems. The grounding impedance can also take into account the inductance per unit length and capacitance per unit length, in addition to the resistance load per unit length and transverse conductance per unit length. The grounding impedance results, for example, from the parallel connection of the ground resistances of the connected-together grounding electrodes. This can include, for example, the impedances of the connected ground wires of overhead lines and the metal sheaths of cables.

The consideration of the local part of the ground resistance, i.e. a determination of the grounding impedance of the local grounding system, may be necessary to verify the correct installation of a (local) grounding device (comparison with calculated/planned values) on the one hand, and to ascertain corrosion effects on the grounding device during repeat tests on the other hand. If the connected systems were also taken into account here, it would only be possible to assess the safety of the entire system, for example an entire overhead line, but no precise statement could be made about the local grounding system of, for example, a specific overhead line pylon.

Various methods are known for determining the local grounding impedance.

In a method for overhead line pylons, for example, the ground wire is removed and thus the connection to other grounding systems is temporarily disconnected for the duration of the measurement. This method provides relatively exact measurement values, but requires a great deal of effort. For example, there is a need for specially trained industrial climbers who climb the mast and remove the ground wire. Various safety aspects have to be taken into account. For example, small electric arcs can occur during removal due to the flow of equalizing currents. Special safety clothing may therefore be required, for example a chainmail suit. Furthermore, the measurement itself can pose a safety problem, as the grounding system is not fully functional during the measuring. In addition, disabling and re-establishing the connecting can be a source of error.

A further method uses a measurement of a current distribution by means of a current measuring device, for example by means of clamp-on ammeters or sensors, e.g. Rogowski sensors. This measurement of the current distribution generally provides sufficiently accurate values but requires a correct-phase current measurement at each relevant connection between the grounding systems, such as each pylon base of an overhead line pylon. The installation of corresponding measuring devices is therefore time-consuming and requires precise execution in order to avoid incorrect measurements. Furthermore, this method requires a sufficiently large test current so that measurement errors caused by the current measuring device used only have an insignificant influence on the measured value.

Furthermore, the local grounding impedance can be preformed easily and quickly using a high-frequency method, which is also specified in EN 50522. However, this requires a relatively high frequency to obtain an accurate measurement value. At typical measurement frequencies of 5 kHz, deviations in the region of 30% occur compared to removing the ground wire. More accurate measurement results are provided by measuring devices that measure at up to 25 kHz. However, this makes the measurement setup more complex. In order to avoid errors caused by coupling at frequencies in the kHz range, for example, it may be necessary to use shielded coaxial cables. Furthermore, parasitic capacitive and inductive couplings can easily distort the measurement.

### SUMMARY OF THE INVENTION

There is a need for improved possibilities for measuring grounding impedances of local grounding devices of power engineering installations, which provide sufficiently accurate measurement results and can be carried out quickly and easily using simple means.

According to the present invention, a method for determining a grounding impedance of a grounding device of a power engineering installation and a device for determining a grounding impedance of a grounding device of a power engineering installation, as are defined in the independent claims, are provided. The dependent claims define embodiments of the invention.

In a method according to the invention for determining a grounding impedance of a grounding device of a power engineering installation, at least two impedance values are determined on the grounding device, while the grounding device is electrically connected to at least one further grounding device of at least one further power engineering installation. For example, the power engineering installation can be an overhead line pylon which is connected to further grounded overhead line pylons via a ground wire while the at least two impedance values are being determined. Each of the at least two impedance values is determined with a respective test current in each case at a specified frequency. For example, when a test current is applied in each case, a corresponding respective voltage can be measured via the grounding and the respective impedance value can be determined in this way. The frequencies of the respective test currents are different. The frequencies of the respective test currents are, for example, in a range below 1 kHz and preferably close to the mains frequency used, in particular in a range from, for example, 10 Hz to 100 Hz. One of the test currents can, for example, have a frequency of 30 Hz and another of the test currents can, for example, have a frequency of 70 Hz. It is possible for more than two impedance values to be determined, for example three or four impedance values at three or four different frequencies. Furthermore, at least one parameter of a model is determined as a function of the at least two impedance values. The model represents the grounding device and at least one further grounding device. If there are more than two impedance values, all of these impedance values can be taken into account when determining the parameters. The at least one parameter comprises an approximate value for the grounding impedance of the grounding device.

By using the model, which represents the grounding device and the at least one further grounding device, test currents with relatively low frequencies can be used, as a result of which the effort required for the measurement is significantly lower than with the high-frequency method. In particular, by using relatively low frequencies, in particular frequencies close to the nominal frequency or mains frequency, can take place, as a result of which the measurement setup is simplified and the influence of potential sources of error, such as capacitive and inductive couplings, is minimized. Furthermore, corresponding devices are frequently already available for generating the test voltages and measuring the impedance values at the relatively low frequencies mentioned above, which can be used in conjunction with the method described above, so that these devices can be reused and the method can be implemented cost-effectively, for example by means of a corresponding processing device or a software program for an existing processing device.

The model used represents an approximation of the real behavior of the high-voltage system. This allows a relatively precise approximate value to be ascertained for the grounding impedance of the grounding device.

According to one embodiment, the approximate value for the grounding impedance in the model substantially corresponds to a local ground resistance of the grounding device. The grounding device 120 of the power engineering installation can for example comprise a grounding network or a meshed grounding electrode. The power engineering installation can comprise an overhead line pylon. Each of the further power engineering installations can also comprise an overhead line pylon. The power engineering installation and the further power engineering installations can be electrically connected to one another via a ground wire. In particular for overhead line pylons that are connected to one another via a ground wire, a high degree of accuracy for the approximate value for the grounding impedance can be achieved with the aid of the model.

According to an embodiment, a total impedance of the further grounding device is represented in the model by a series connection of a reactance, e.g. an inductance, and a resistance. For example, the reactance and the resistance can represent a sum of inductances, capacitances, resistances and/or conductances of a chain conductor, which are formed by the ground wire and the grounding devices of the further power engineering installations. In particular in the case of overhead line pylons, using the model, such a depiction of the ground wire and the further grounding devices coupled to it provides a high degree of precision for the approximate value for the local grounding impedance.

In one embodiment, the determination of the at least one parameter of the model comprises a numerical approximation method. Alternatively or additionally, the at least one parameter of the model can be determined by applying a genetic algorithm. For example, the at least one parameter of the model can be determined in such a way that a Euclidean distance in the complex resistance plane between impedance values of the model and the impedance values determined from the measurements becomes minimal.

According to a further embodiment, to determine a respective impedance value of the at least two impedance values, the respective test current is fed into the grounding device of the power engineering installation with the specified frequency by means of an auxiliary ground electrode. The auxiliary ground electrode can, for example, be provided at a distance of some meters from the grounding device, for example at a distance of 10 to 100 m from a grounding network or a meshed grounding electrode. A current source which generates the respective test current is, for example, coupled to the auxiliary ground electrode and a connection of the grounding device. A respective voltage is measured between the grounding device and a probe arranged spaced apart from the grounding device. The probe can also be provided at a distance of some meters from the grounding device, for example at a distance of 10 to 100 m from a grounding network or a meshed grounding electrode. The respective impedance value is determined as a function of the respective test current, the specified frequency of the respective test current and the voltage measured in each case.

In a further method, a reduction factor of a grounding device of a power engineering installation, which is coupled to at least one further grounded power engineering installation, is determined. The reduction factor represents the division of current between the local grounding electrode and the connected other grounding systems. In the method, a grounding impedance of the grounding device is determined as described above. Furthermore, a total impedance for the grounding device and the other grounding devices connected to it is at least approximately determined or estimated using the model. The reduction factor is determined as a function of the grounding impedance and the total impedance. Therefore, in addition to the measurements for the previously described determining of the grounding impedance, no further measurements are therefore required in order to determine the reduction factor, so that the reduction factor can be determined in a simple manner with the aid of the model and the measurement values already available.

The method described previously can be performed automatically by means of a test apparatus for the power engineering installation. For example, the auxiliary ground electrode for the test current feed and the probe for the voltage measurement can be installed and coupled to the test apparatus via appropriate electrical connections. Furthermore, the test apparatus can be electrically connected to the grounding device. The test apparatus can then automatically feed in the various test currents with the various frequencies one after the other and measure the corresponding voltages between the probe and the grounding device and automatically determine the corresponding impedance values. Alternatively, the various test currents with the various frequencies can also be fed in simultaneously, i.e. superimposed, whereby the relevant frequency components in each case are recovered from the measured signal with the aid of appropriate filters. With the aid of the model, which can be provided in the test device and which represents the grounding device and the at least one further grounding device, the test device can automatically determine an approximate value for the grounding impedance of the grounding device. Furthermore, the test device can automatically determine a reduction factor for the grounding device. The automatically determined values can, for example, be displayed on a display device of the test device. Since the model takes into account other grounding devices to which the local grounding device is electrically connected at the time of the measurement, it is not necessary to decouple the local grounding device from these other grounding devices. For example, a ground wire can continue to be coupled to the overhead line pylon and other overhead line pylons during the measurement on an overhead line pylon.

According to the present invention, a device for determining a grounding impedance of a grounding device of a power engineering installation is provided. The device comprises a measuring device which is configured to determine at least two impedance values on the grounding device, while the grounding device is electrically connected to at least one further grounding device of at least one further power engineering installation. Each of the at least two impedance values is determined with a respective test current at a specified frequency. The frequencies of the respective test currents are different. The device furthermore comprises a processing device which is configured to determine at least one parameter of a model, which represents the grounding device and the at least one further grounding device, as a function of the at least two impedance values. The at least one parameter comprises an approximate value for the grounding impedance of the grounding device, i.e. the local grounding impedance.

The device can be configured to perform the method described above, in particular such that the method steps of the methods described above are carried out automatically by the device.

A test apparatus for a power engineering installation may comprise the device described above. The test apparatus may have further functionalities, for example functionalities for wiring and polarity tests, burden measurements, protection relay tests, transmission measurements for current and voltage transformers or (microohm) resistance measurements.

The invention described is applicable to both high-voltage devices and medium-voltage or low-voltage equipment as a power engineering installation whose grounding impedance is determined. Accordingly, the power engineering installation whose grounding impedance is determined can be, for example, a high-voltage pylon or a low-voltage pylon.

### BRIEF DESCRIPTION OF THE FIGURES

The invention is explained in greater detail below using preferred embodiments, with reference to the drawings. In the drawings, identical reference numbers indicate identical elements.

FIG. 1 schematically shows a grounded overhead line pylon which is connected to a number of further overhead line pylons via ground wire.

FIG. 2 schematically shows a measuring arrangement for determining a grounding impedance of a grounding device of an overhead line pylon according to an embodiment.

FIG. 3 schematically shows a test apparatus for a power engineering installation according to one embodiment.

FIG. 4 shows a method for determining a grounding impedance of a grounding device of a power engineering installation according to one embodiment.

FIG. 5 schematically shows a model of a local ground resistance of a grounding device of a power engineering installation in connection with a chain conductor which is formed by adjacent power engineering installations and their grounding devices.

FIG. 6 shows a solution space of a genetic algorithm which is applied to determine a grounding impedance of a grounding device with the aid of the model from FIG. 5.

FIG. 7 shows a depiction of a frequency response curve of a total impedance on the grounding device of the power engineering installation, which is modelled with the aid of the model from FIG. 5.

### DETAILED DESCRIPTION OF THE EXEMPLARY EMBODIMENTS

The present invention will be explained in greater detail below using preferred embodiments, with reference to the drawings. In the figures, the same reference numbers indicate the same or similar elements. The figures are schematic depictions of various embodiments of the invention. Elements depicted in the figures are not necessarily depicted true to scale. On the contrary, the different elements depicted in the figures are reproduced in such a manner that their function and their purpose are comprehensible to the person skilled in the art.

Connections and couplings depicted in the figures between functional entities and elements can be implemented as entity and elements can be implemented as direct or indirect connections or couplings. A connection or coupling can be implemented in a wired or wireless manner.

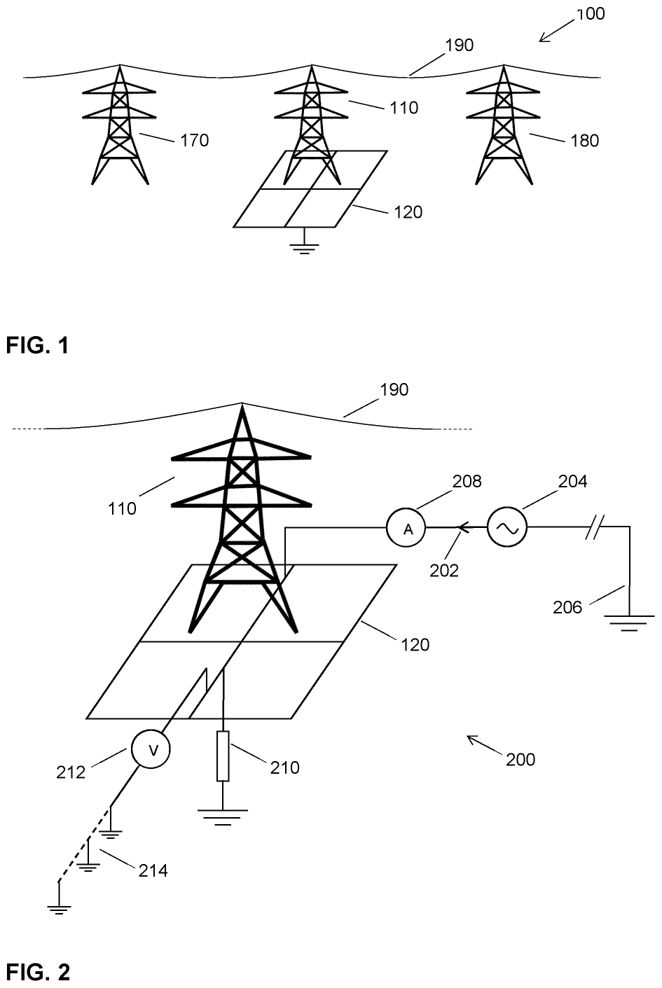

FIG. 1 schematically shows a section of a high-voltage transmission path 100 with three overhead line pylons 110, 170 and 180. The three overhead line pylons 110, 170 and 180 are coupled to each other via a ground wire 190, so that the grounding devices of the overhead line pylons 110, 170 and 180 are electrically coupled to one another. As an example, a grounding device 120 assigned to the overhead line pylon 110 is depicted for the overhead line pylon 110. The grounding device 120 can for example comprise a grounding network or a meshed grounding electrode. The overhead line pylons 110, 170 and 180 are only one example of power engineering installations, which each comprise a corresponding grounding device and are electrically connected to one another. Other examples of corresponding power engineering installations are for example high-voltage transformers, high-voltage generators or high-voltage switching devices. Although reference is made mainly to overhead line pylons below, the methods and techniques described below can also be applied to other power engineering installations.

FIG. 2 schematically shows a measuring arrangement 200 for determining a local grounding impedance of the grounding device 120 of the overhead line pylon 110. It should be noted that the measurement can be performed while the overhead line pylon 110 is coupled via the ground wire 190 to further overhead line pylons, for example the overhead line pylons 170 and 180. This means that the grounding devices of the overhead line pylons 170 and 180 and any further power engineering installations, which are coupled to the overhead line pylon 110 via the ground wire 190, are electrically connected to one another. In other words, a measurement at the grounding device 120 is influenced by the grounding devices of the overhead line pylons 170 and 180 and additional power engineering installations.

In order to verify the correct unit and mode of operation of the grounding device 120 of the overhead line pylon 110, for example to compare it with calculated or planned values or to ascertain corrosion effects on the grounding device 120 during repeat tests, it is necessary to determine a local ground resistance of the grounding device 120. FIG. 2 depicts this local ground resistance through a grounding impedance 210.

In the case of the measuring arrangement 200, a test current 202 is fed into the grounding device 120 from a current source 204 by means of an auxiliary ground electrode 206. A value of the test current 202 can, for example, be measured with a current measuring apparatus 208 and supplied to a processing device not shown in FIG. 2. Alternatively or additionally, the current source 204 can transmit the value of the currently output test current 202 to the processing device. The auxiliary ground electrode 206 can be arranged at a specified sufficient distance from the grounding device 120. A spacing between the auxiliary ground electrode 206 and the grounding device 120 may be some meters, for example 10m to 100 m. The current source 204 is capable of generating the test current at a specified frequency. The specified frequency may, for example, be in a range from 10 Hz to several 100 Hz, for example in a range from 20 Hz to 100 Hz. The current source 204 is capable of generating the test current at at least two different frequencies, for example at a frequency of 30 Hz and a frequency of 70 Hz.

With the aid of a voltage measuring apparatus 212, a voltage is measured by means of a voltage probe 214 between the grounding device 120 and the voltage probe 214. The voltage probe 214 is arranged at a sufficient spacing from the grounding device 120 and also at a sufficient spacing from the auxiliary ground electrode 206. A spacing between the voltage probe 214 and the grounding device 120 can be some meters, for example 10m to 100 m. The voltage measuring apparatus is able to measure voltages at different frequencies, in particular at frequencies which are used by the current source 204 to generate the test current. The voltage measuring apparatus 212 may further be capable of determining a phase between the test current generated by the current source 204 and the voltage measured by the voltage measuring apparatus 212. For this purpose, the voltage measuring apparatus can be coupled to the current source 204 or the current measuring apparatus 208, for example. Alternatively or additionally, the current measuring apparatus 208, the current source 204 and/or the voltage measuring apparatus 212 can be connected to the processing device not shown in FIG. 2, which can ascertain a phase position between the test current and the measured voltage using current values of test current and measured voltage values.

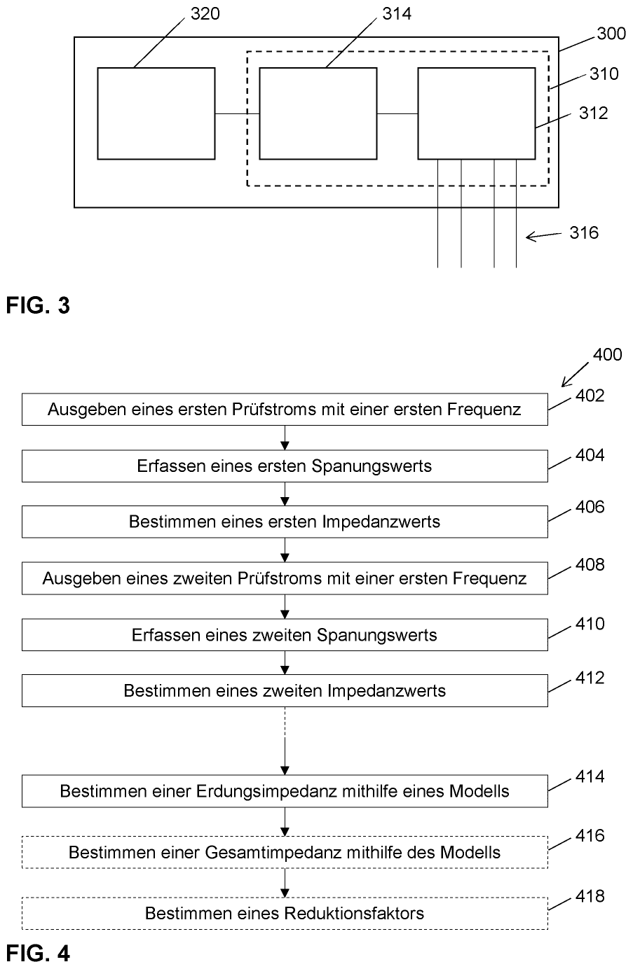

FIG. 3 schematically shows a test apparatus 300 which can be used for the measuring arrangement shown in FIG. 2. The test apparatus 300 comprises a device 310 for determining a grounding impedance as well as further components such as a user interface with a display and control elements as well as a power supply. These further components are summarized in FIG. 3 as block 320. The device 310 comprises a measuring device 312 and a processing device 314. The measuring device 312 may, for example, comprise the current source 204, the current measuring apparatus 208 and the voltage measuring apparatus 212, which were described in connection with FIG. 2. The measuring device 312 can be coupled to the grounding device 120, the voltage probe 214 and the auxiliary ground electrode 206 via corresponding connection lines 316. The measuring device 312 is thus capable of determining two or more impedance values at the grounding device 120, which are determined at a respective test current at a respective specified frequency, wherein the respective frequencies of the respective currents are different. The impedance values are transmitted from the measuring device 312 to the processing device 314. The processing device 314 can, for example, be a microprocessor controller on which a computer program is executed. The processing device 314 can transmit commands to the measuring device 312 in order to control the measuring device 312.

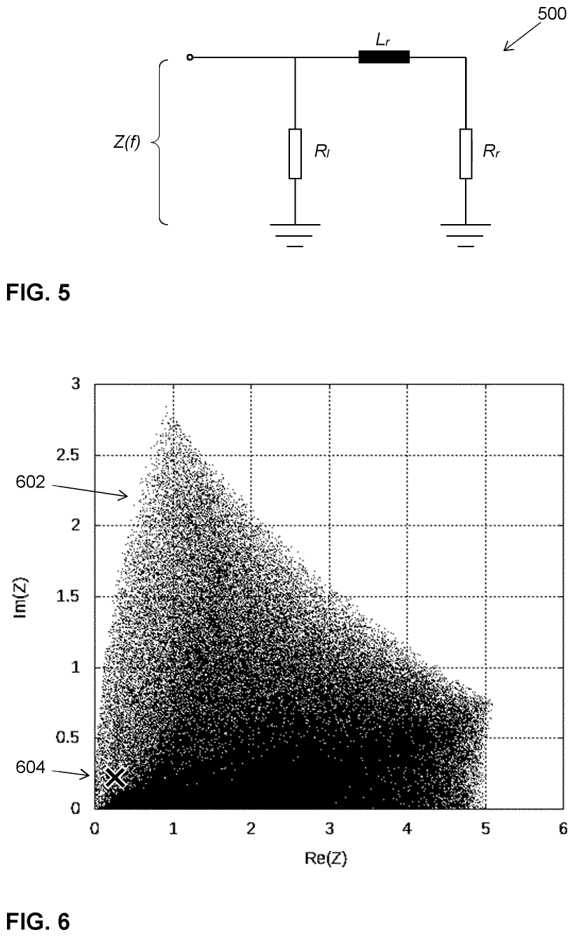

For example, the processing device 314 can activate the measuring device 312 in order to output a test current at a specified frequency. Furthermore, a model is implemented in the computer program which models the total impedance of the grounding via the grounding device 120 and via the grounding of the further overhead line pylons 170, 180 connected via the ground wire 190 and, if applicable, further power engineering installations, without details of the grounding of the further overhead line pylons 170, 180 and further power engineering installations having to be known in detail in the model. Parameters of the model comprise, in particular, the local grounding impedance 210, so that this can be determined with the aid of the model. The model will be described in detail in connection with FIG. 5.

With reference to FIG. 4, the mode of operation of the testing device 300 in the measuring arrangement 200 will be described below. The method 400 shown in FIG. 4 comprises method steps 402 to 418, wherein in particular method steps 416 and 418 are optional.

In step 402, a first test current with a first frequency f₁, for example a frequency of 30 Hz, is fed into the grounding device 120 using the auxiliary ground electrode 206. A current intensity of the first test current may for example be a few amperes, for example in the range of 1 A to 50 A. However, depending on the conditions, a lower current, for example in the range of 100-200 mA, may also be sufficient. In step 404, a first voltage between the grounding device 120 and the voltage probe 214 is measured and a phase position of the first voltage relative to the first test current is determined. The generation of the first test current and the measurement of the first voltage can for example be carried out by means of the measuring device 312 under the control of the processing device 314. On the basis of the first test current, the first voltage and the phase position of the first voltage relative to the first test current, the processing device 314 can determine a first impedance value Zm₁ for the first frequency f in step 406.

In step 408, a second test current with a second frequency f₂, for example a frequency of 70 Hz, is fed into the grounding device 120 using the auxiliary ground electrode 206. A current intensity of the second test current may substantially correspond to the current intensity of the first test current, although this is not necessary, and the second test current may also deviate from the first test current. In step 410, a second voltage between the grounding device 120 and the voltage probe 214 is measured and a phase position of the second voltage relative to the second test current is determined. For example, the measuring device 312 may, under the control of the processing device 314, generate the second test current and measure the second voltage. From the second test current, the second voltage and the phase between the second voltage and the second test current, the processing device 314 can determine a second impedance value Zm₂ for the second frequency f₂ in step 412.

As depicted by the partially dashed arrow in FIG. 4, further impedance values at further frequencies can be determined between step 412 and step 414 by feeding-in further test currents and measuring further voltages and used in the determination of the grounding impedance 210 described below. For reasons of clarity, however, the use of only two impedance values, which were determined as described above, is essentially explored below.

In an exemplary performance of method 400, the first test current is fed in at a frequency f₁ of 30 Hz and a corresponding impedance Zm₁ is measured and then the second test current is fed in at a frequency f₂ of 70 Hz and a corresponding impedance Zm₂ is measured. The result is depicted in the following table (1), with the impedances Zm being entered according to magnitude and phase.

TABLE 1

| Frequency | \|Zₘ\| | Phase (Zₘ) |
|---|---|---|
| 30.0 Hz | 0.22 Ohm | 37.89° |
| 70.0 Hz | 0.37 Ohm | 48.60° |

To determine the grounding impedance 210, a model is used which models the grounding device 120 of the overhead line pylon 110 as well as the ground wire 190 and the further overhead line pylons 170, 180 and their grounding devices connected thereto.

FIG. 5 shows a model 500 in the form of an equivalent circuit diagram for the grounding device 120 of the overhead line pylon 110 and the further overhead line pylons 170, 180, and their grounding devices, which are connected thereto via the ground wire 190. In model 500, Rₗ represents the local ground resistance. Especially with a grounding network or meshed grounding electrode, the inductive component is negligible for an approximate solution. Therefore, the local ground resistance Rₗ can be regarded as a purely ohmic resistance. Lᵣ and Rᵣ represent the sum of the resistances, inductances and capacitances of a chain conductor, which is formed by the ground wire 190 at the overhead line pylon 110 and the grounding devices of the neighboring overhead line pylons 170, 180. Based on this model, the total grounding impedance Z(f) as a function of the frequency is given by the following equation (1):

$$Z ( f ) = \frac{1}{\frac{1}{{R}_{l}} + \frac{1}{j 2 π {fL}_{r} + {R}_{r}}} \qquad ( 1 )$$

In step 414, the processing device 314 determines suitable values for Rₗ, Lᵣ and Rᵣ, which are determined in such a way that the resulting grounding impedance Z(f) corresponds as well as possible to the measurement values Zm=Rm+jXm at the respective frequency. This can be done, for example, by minimizing a Euclidean distance in the complex resistance plane according to the following equation (2):

$$δ = {\sum }_{n = 1}^{M} \vert Z ( {f}_{n} ) - {Z}_{m , n} \vert = {\sum }_{n = 1}^{M} \sqrt{{( R ( {f}_{n} ) - {R}_{m , n} )}^{2} + {( X ( {f}_{n} ) - {X}_{m , n} )}^{2}} \qquad ( 2 )$$

Here, M corresponds to the number of impedance values Zmₙ ascertained as previously described with reference to steps 402 to 412. At least two impedance values are used to determine the values of the parameters Rₗ, Lᵣ and Rᵣ, i.e. Mis greater than or equal to two. If more than two impedance values are available, a determination accuracy of the values of the parameters Rₗ, Lᵣ and Rᵣ can be improved. In the equation (2), R(f) is the real part of the grounding impedance Z(fₙ) of the model at the frequency fₙ of the measured impedance value Zmₙ, and X(fₙ) is the imaginary part of the grounding impedance Z(fₙ) of the model at the frequency in of the measured impedance value Zmₙ. Rmₙ and Xmₙ are the real and imaginary parts of the measured impedance value Zmₙ.

The processing device 314 uses an optimization method to determine suitable values for Rₗ, Lᵣ and Rᵣ, so that δ is minimal. For this purpose, the processing device 314 can use a numerical approximation method or a genetic algorithm, for example. When using a genetic algorithm, equation (2) is used as the fitness function and thus δ is minimized.

A genetic algorithm, implemented by way of example, provides a result shown in FIG. 6 for the above-mentioned measured values. FIG. 6 shows the solution space 600 with the initial population 602 (black dots) of the genetic algorithm at 50 Hz. A minimum δ for equation (2) was found at position 604 (marked by a white-framed ‘x’) and provided the following parameter set for the model:

TABLE 2

| Rₗ | Lᵣ | Rᵣ | δ |
|---|---|---|---|
| 1.255 Ohm | 891 μH | 0.192 Ohm | 0.0135 Ohm |

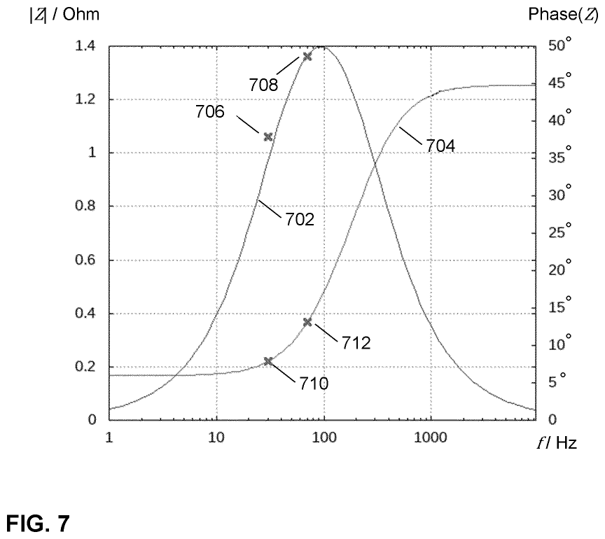

For the model shown in FIG. 5, the parameters in Table (2) result in a curve of the impedance Z(f) over the frequency f as shown in FIG. 7. A magnitude of the impedance Z(f) over the frequency f is shown as graph 702 and a phase of the impedance Z(f) over the frequency f is shown as graph 704. The corresponding values 706 and 708, ascertained from the measurement, for the phase of the impedance at 30 Hz and 70 Hz, respectively, and the corresponding values 710 and 712, ascertained from the measurement, for the magnitude of the impedance at 30 Hz and 70 Hz, respectively, match relatively well with the model.

On the basis of the parameters which have been ascertained for the model shown in FIG. 5, the grounding resistance Rₗ of the local grounding system can thus be calculated. The local grounding resistance provides information about the quality of the grounding system. When calculating a grounding system to be newly erected, a target value for the grounding resistance is calculated or a certain design of the grounding system is stated, from which it can be assumed that the resulting grounding resistance after erection of the pole is below a certain limit value. After erection, the grounding resistance determined with the aid of the model can be compared with the target value and it is thus possible to check whether it corresponds to the specification with sufficient accuracy. If the local grounding resistance Rₗ deteriorates over time, this may indicate corrosion of the grounding system in the ground.

On the basis of the parameters which have been ascertained for the model shown in FIG. 5, a reduction factor r can thus also be calculated in addition to the grounding resistance Rₗ of the local grounding system. The reduction factor r represents a division of current between the local grounding device 120 and the associated other grounding systems in accordance with equation (3).

$$r = \frac{{I}_{l}}{{I}_{g}} = \frac{{I}_{l}}{{I}_{l} + {I}_{r}} \qquad ( 3 )$$

Where r is the proportion Iₗ of the total current I_{g}. The total current I_{g} is made up of the current Iₗ, which flows into the local grounding system 120, and the current Iᵣ, which flows into the neighboring grounding systems via the ground wire 190. The total current I_{g} is divided proportionally to the corresponding impedances according to equation (4).

$$r ( f ) = \frac{\frac{1}{{R}_{l}}}{\frac{1}{{R}_{l}} + \frac{1}{j 2 π {fL}_{r} + {R}_{r}}} = \frac{Z ( f )}{{R}_{l}} \qquad ( 4 )$$

For example, the total impedance Z(f) can first be determined in step 416 and the reduction factor r can be determined in step 418 from the total impedance Z(f) and the grounding resistance Rₗ according to equation (4). Thus, the reduction factor r can be ascertained very simply, at least approximately, without the need to perform an additional measurement of the current flow or to remove the ground wire 190. In the above example in table (1), the reduction factor rat 50 Hz has a value of r(50 Hz)=0,164+j0,162 with a magnitude of |r(50 Hz)|=0,23.

On the basis of the reduction factor r, it is possible to determine how high these voltages would be without other connected grounding systems when measuring step or touch voltages, for example. Such voltages can be relevant for so-called worst-case scenarios, for example.

1. A method for determining a grounding impedance of a grounding device of a power engineering installation, comprising:
determining at least two impedance values on the grounding device, while the grounding device is electrically connected to at least one further grounding device of at least one further power engineering installation, wherein each of the at least two impedance values is determined with a respective test current at a specified frequency, wherein the frequencies of the respective test currents are different,
determining at least one parameter of a model, which represents the grounding device and the at least one further grounding device, as a function of the at least two impedance values, wherein the at least one parameter comprises an approximate value for the grounding impedance of the grounding device.

2. The method according to claim 1, wherein the grounding device of the power engineering installation comprises a grounding network or a meshed grounding electrode.

3. The method according to claim 1, wherein, in the model, the approximate value for the grounding impedance is a local ground resistance of the grounding device.

4. The method according to claim 1, wherein the power engineering installation and/or the at least one further power engineering installation respectively comprise one overhead line pylon.

5. The method according to claim 1, wherein the power engineering installation and the at least one further power engineering installation are electrically connected to one another via a ground wire.

6. The method according to claim 5, wherein, in the model, a total impedance of the at least one further grounding device is represented by a series connection of a reactance and a resistance.

7. The method according to claim 6, wherein the reactance and the resistance represent a sum of inductances and capacitances of a chain conductor formed by the ground wire and the at least one further grounding device.

8. The method according to claim 1, wherein the determination of the at least one parameter of the model comprises a numerical approximation method.

9. The method according to claim 1, wherein the determination of the at least one parameter of the model comprises applying a genetic algorithm.

10. The method according to claim 1, wherein the at least one parameter of the model is determined in such a way that a Euclidean distance in the complex resistance plane between impedance values of the model and the determined at least two impedance values becomes minimal.

11. The method according to claim 1, wherein, to determine a respective impedance value of the at least two impedance values, the respective test current is fed into the grounding device of the power engineering installation at the specified frequency by means of an auxiliary ground electrode and a respective voltage is measured between the grounding device and a probe arranged spaced apart from the grounding device, wherein the respective impedance value is determined as a function of the respective test current, the specified frequency of the respective test current and the voltage measured in each case.

12. A method for determining a reduction factor of a grounding device of a power engineering installation which is coupled to at least one further grounded power engineering installation, comprising:
determining a grounding impedance of the grounding device wherein determining the grounding impedance comprises: determining at least two impedance values on the grounding device, while the grounding device is electrically connected to at least one further grounding device of at least one further power engineering installation, wherein each of the at least two impedance values is determined with a respective test current at a specified frequency, wherein the frequencies of the respective test currents are different, and determining at least one parameter of a model, which represents the grounding device and the at least one further grounding device, as a function of the at least two impedance values, wherein the at least one parameter comprises an approximate value for the grounding impedance of the grounding device,
determining a total impedance for the grounding device and the at least one further grounding device, which is connected thereto, by means of the model and the at least one parameter which has been determined for the model, and
determining the reduction factor as a function of the grounding impedance and the total impedance.

13. The method according to claim 1, wherein the method is performed automatically by a test apparatus for the power engineering installation.

14. A device for determining a grounding impedance of a grounding device of a power engineering installation, comprising:
a measuring device which is configured to determine at least two impedance values on the grounding device, while the grounding device is electrically connected to at least one further grounding device of at least one further power engineering installation, wherein each of the at least two impedance values is determined with a respective test current at a specified frequency, wherein the frequencies of the respective test currents are different, and
a processing device which is configured to determine at least one parameter of a model, which represents the grounding device and the at least one further grounding device, as a function of the at least two impedance values, wherein the at least one parameter comprises an approximate value for the grounding impedance of the grounding device.

15. The device according to claim 14, wherein the grounding device of the power engineering installation comprises a grounding network or a meshed grounding electrode.

16. A test apparatus for a power engineering installation, comprising a device according to claim 14.

17. The device according to claim 14, wherein:
the power engineering installation and the at least one further power engineering installation are electrically connected to one another via a ground wire,
in the model, a total impedance of the at least one further grounding device is represented by a series connection of a reactance and a resistance, and
the reactance and the resistance represent a sum of inductances and capacitances of a chain conductor formed by the ground wire and the at least one further grounding device.

18. The device according to claim 14, wherein the processing device is configured to determine the at least one parameter of the model in such a way that a Euclidean distance in the complex resistance plane between impedance values of the model and the determined at least two impedance values becomes minimal.

19. The device according to claim 14, wherein the measuring device is configured to determine a respective impedance value of the at least two impedance values by feeding the respective test current into the grounding device of the power engineering installation at the specified frequency by means of an auxiliary ground electrode and a respective voltage is measured between the grounding device and a probe arranged spaced apart from the grounding device, wherein the respective impedance value is determined as a function of the respective test current, the specified frequency of the respective test current and the voltage measured in each case.

20. The device according to claim 14, wherein the processing device is configured to determine a total impedance for the grounding device and the at least one further grounding device, which is connected thereto, by means of the model and the at least one parameter which has been determined for the model, and determine a reduction factor of the grounding device as a function of the grounding impedance and the total impedance
